(19) United States
(12) Patent Application Publication
(10) Pub. No.: US 2024/0172356 A1
(43) Pub. Date: May 23, 2024

(54) PRINTED CIRCUIT BOARDS INCLUDING STRUCTURES FOR SUPPRESSING RADIATION

(71) Applicant: Intel Corporation, Santa Clara, CA (US)

(72) Inventors: Tejasweeni D LINGAYAT, Dapoli (IN); Maruti TAMRAKAR, Durg (IN); Sudarshan SOLANKI, Bangalore (IN); Bala SUBRAMANYA, Bangalore (IN); Yagnesh Vinodrai WAGHELA, Bangalore (IN)

(21) Appl. No.: 18/056,267

(22) Filed: Nov. 17, 2022

(51) Int. Cl. H05K 1/02; H05K 1/11

(52) U.S. Cl. CPC H05K 1/023; H05K 1/0218; H05K 1/115

(57) ABSTRACT

A printed circuit board includes a ground plane, a power plane having a first main surface and a second main surface opposite to the first main surface, wherein the second main surface faces the ground plane and a shielding structure partially covering the power plane. The shielding structure includes a metal structure covering a peripheral area of the first main surface from a direction facing the first main surface and a plurality of vias electrically and mechanically coupling the metal structure to the ground plane.

### TECHNICAL FIELD

Various embodiments generally relate to printed circuit boards including power planes.

### BACKGROUND

Power planes are usually metal (e.g., copper) shapes formed on printed circuit board (PCB) that are electrically connected to a power supply. Power planes act as reference for signals. Some of the common examples are double data rate (DDR) power planes or memory power planes (+VDD/+VDDQ), Fully integrated voltage regulator (FIVR) power planes (+VCCIN_AUX), and digital liner voltage regulator DLVR power plane (+VCCIA). These types of power planes carry significant noise in gigahertz frequency range. Further, if these types power planes are routed on a PCB surface layer, they can radiate noise in radio frequency band which causes interference to Long-Term Evolution (LTE), Fifth-Generation (5G) and Wi-Fi radios.

Typically, RF capacitors are used as a decoupling path to reduce the Radio Frequency Interference (RFI) from these power plane. However, a single capacitor with a given value may not be effective enough for the entire bandwidth of radio frequency. In such cases multiple decoupling capacitors are clubbed into one set and such sets are repeated at intervals. For example, to reduce RFI noise from DDR (VDDQ) power plane, a 3 pF and a 15 pF capacitor pair may be added at every 12 mm distance at the starting and end of the power shape. FIG. 1 shows an example of a PCB 100 power plane 110 with capacitor pair 120 for a power plane coupled to silicon-on-chip 130 and DDR integrated circuits 140.

In general, RFI noise leakage is typically dealt by either routing the power shape on the inner layers, by adding RF capacitors on the surface routed power shape, by adding absorbers on the power plane or even metal shield enclosures are added to cover the exposed power shapes. All these solutions are effective, but they need additional cost and space for implementation. For thin and light form factors, height is major constraint for addition of EMI absorber or a conventional metal shield.

### BRIEF DESCRIPTION OF THE DRAWINGS

In the drawings, like reference, characters generally refer to the same parts throughout the different views. The drawings are not necessarily to scale; emphasis is instead generally being placed upon illustrating the principles of the invention. In the following description, various embodiments of the invention are described with reference to the following drawings, in which:

FIG. 1 shows an example of a printed circuit board including a power plane and integrated circuits.

FIGS. 2A-2B shows another example of a printed circuit board (PCB) section including generated radiation.

FIGS. 3A-3C shows a printed circuit board (PCB) section according to at least one example of present disclosure.

FIG. 4 shows a block diagram of an electronic assembly according to at least one example of the present disclosure.

FIG. 5 shows a method for forming a printed circuit board according to at least one example of the present disclosure.

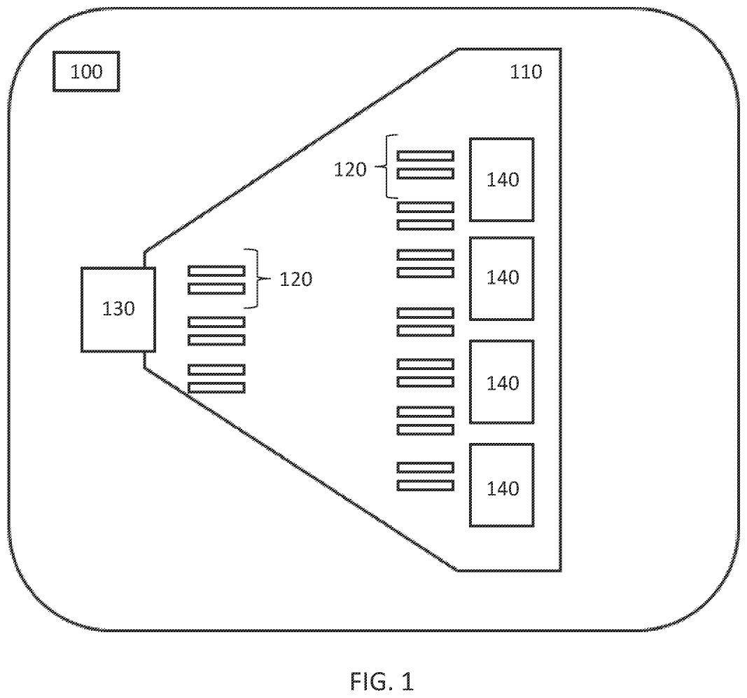

### DESCRIPTION

The following detailed description refers to the accompanying drawings that show, by way of illustration, specific details and embodiments in which the invention may be practiced.

The word “exemplary” is used herein to mean “serving as an example, instance, or illustration.” Any embodiment or design described herein as “exemplary” is not necessarily to be construed as preferred or advantageous over other embodiments or designs.

The words “plurality” and “multiple” in the description or the claims expressly refer to a quantity greater than one. The terms “group (of)”, “set [of]”, “collection (of)”, “series (of)”, “sequence (of)”, “grouping (of)”, etc., and the like in the description or in the claims refer to a quantity equal to or greater than one, i.e., one or more. Any term expressed in the plural form that does not expressly state “plurality” or “multiple” likewise refers to a quantity equal to or greater than one. The terms “proper subset”, “reduced subset”, and “lesser subset” refer to a subset of a set that is not equal to the set, i.e., a subset of a set that contains fewer elements than the set.

The terms “at least one” and “one or more” may be understood to include a numerical quantity greater than or equal to one (e.g., one, two, three, four, [ . . . ], etc.).

As used herein, unless otherwise specified, the use of the ordinal adjectives “first”, “second”, “third”, etc., to describe a common object merely indicate that different instances of like objects are being referred to, and are not intended to imply that the objects so described must be in a given sequence, either temporally, spatially, in ranking, or in any other manner.

As used herein, the phrase “A and/or B” means (A), (B), or (A and B). For the purposes of the present disclosure, the phrase “A, B, and/or C” means (A), (B), (C), (A and B), (A and C), (B and C), or (A, B, and C).

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in the form of a pointer. However, the term data is not limited to the aforementioned examples and may take various forms and represent any information as understood in the art.

The term “processor” or “controller” as, for example, used herein may be understood as any kind of entity that allows handling data, signals, etc. The data, signals, etc., may be handled according to one or more specific functions executed by the processor or controller.

A processor or a controller may thus be or include an analog circuit, digital circuit, mixed-signal circuit, logic circuit, processor, microprocessor, Central Processing Unit (CPU), Neuromorphic Computer Unit (NCU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

A “circuit” as used herein is understood as any kind of logic-implementing entity, which may include special-purpose hardware or a processor executing software. A circuit may thus be an analog circuit, digital circuit, mixed-signal circuit, logic circuit, processor, microprocessor, signal processor, Central Processing Unit (“CPU”), Graphics Processing Unit (“GPU”), Neuromorphic Computer Unit (NCU), Digital Signal Processor (“DSP”), Field Programmable Gate Array (“FPGA”), integrated circuit, Application Specific Integrated Circuit (“ASIC”), etc., or any combination thereof. Any other kind of implementation of the respective functions, which will be described below in further detail, may also be understood as a “circuit.” It is understood that any two (or more) of the circuits detailed herein may be realized as a single circuit with substantially equivalent functionality. Conversely, any single circuit detailed herein may be realized as two (or more) separate circuits with substantially equivalent functionality. Additionally, references to a “circuit” may refer to two or more circuits that collectively form a single circuit.

As utilized herein, terms “module”, “component,” “system,” “circuit,” “element,” “interface,” “slice,” “circuitry,” and the like are intended to refer to a set of one or more electronic components, a computer-related entity, hardware, software (e.g., in execution), and/or firmware. For example, circuitry or a similar term can be a processor, a process running on a processor, a controller, an object, an executable program, a storage device, and/or a computer with a processing device. By way of illustration, an application running on a server and the server can also be circuitry. One or more circuits can reside within the same circuitry, and circuitry can be localized on one computer and/or distributed between two or more computers. A set of elements or a set of other circuits can be described herein, in which the term “set” can be interpreted as “one or more.”

As used herein, a “signal” may be transmitted or conducted through a signal chain in which the signal is processed to change characteristics such as phase, amplitude, frequency, and so on. The signal may be referred to as the same signal even as such characteristics are adapted. In general, so long as a signal continues to encode the same information, it may be considered the same signal.

As used herein, a signal that is “indicative of” a value or other information may be a digital or analog signal that encodes or otherwise communicates the value or other information in a manner that can be decoded by and/or cause a responsive action in a component receiving the signal. The signal may be stored or buffered in a computer-readable storage medium prior to its receipt by the receiving component. The receiving component may retrieve the signal from the storage medium. Further, a “value” that is “indicative of” some quantity, state, or parameter may be physically embodied as a digital signal, an analog signal, or stored bits that encode or otherwise communicate the value.

It will be understood that when an element is referred to as being “connected” or “coupled” to another element, it can be physically connected or coupled to the other element such that current and/or electromagnetic radiation (e.g., a signal) can flow along a conductive path formed by the elements. Intervening conductive, inductive, or capacitive elements may be present between the element and the other element when the elements are described as being coupled or connected to one another. Further, when coupled or connected to one another, one element may be capable of inducing a voltage or current flow or propagation of an electromagnetic wave in the other element without physical contact or intervening components. Further, when a voltage, current, or signal is referred to as being “applied” to an element, the voltage, current, or signal may be conducted to the element by way of a physical connection or by way of capacitive, electromagnetic, or inductive coupling that does not involve a physical connection.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A lateral direction is understood to mean a direction that runs, in particular, parallel to a main extension surface of the component, in particular of the converter layer. A vertical direction is understood to mean a direction that is oriented, in particular, perpendicular to the main extension surface of the component and/or the converter layer. The vertical direction and the lateral direction are approximately orthogonal to each other.

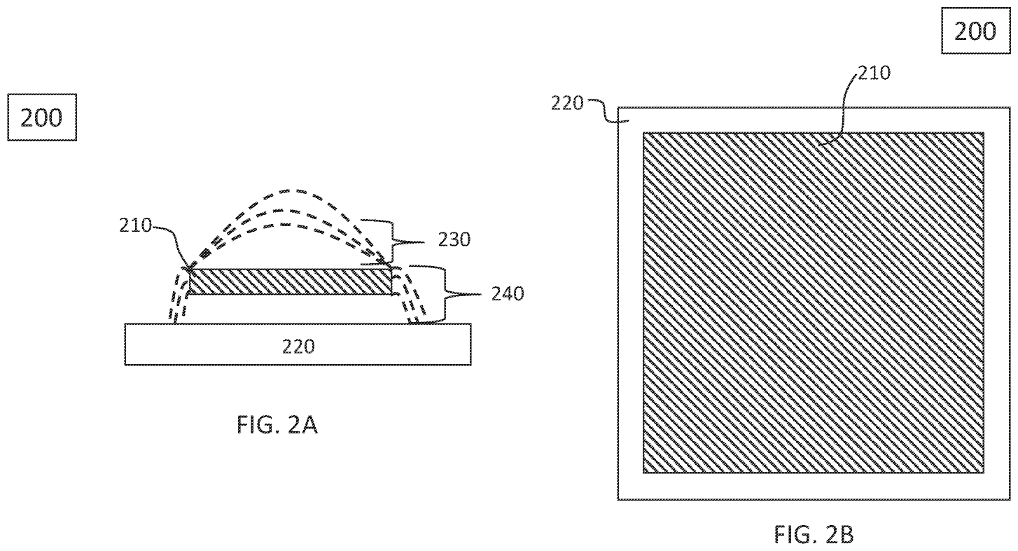

FIGS. 2A-2B shows an example of a printed circuit board (PCB) section 200. The PCB section 200 may be part of a multi-layer PCB. FIG. 2A is a side-view of the PCB section 200 and FIG. 2B is a top plan view of the PCB section 200. The PCB section 200 may be a top or bottom layer of PCB. The PCB section 200 includes a power plane 210 disposed laterally over a ground plane 220.

Power planes, such as the power plane 210 can couple to a power voltage. Such power planes can often produce radiation that adversely affects the operation of other devices or circuits. FIG. 2A shows side radiation produced by the power plane 210 connected to a power supply. This radiation behavior of the power plane 210 is similar to that of patch antennas. In particular, the power plane 210 produces a radiating field 230 and fringing field 240.

According to one or more examples of the present disclosure, a reduction of the radio frequency (RF) noise without disturbing the power shape can be achieved by blocking and/or interrupting the radiation path.

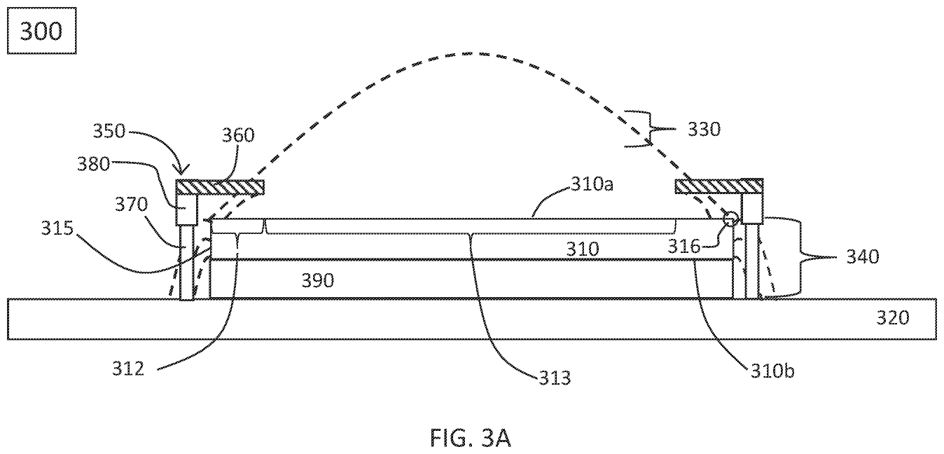

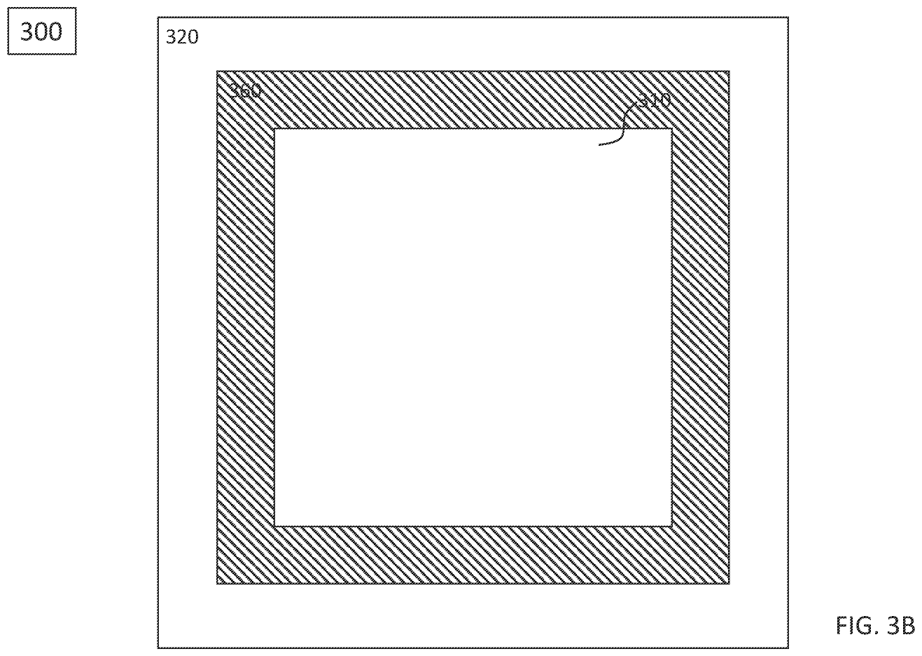

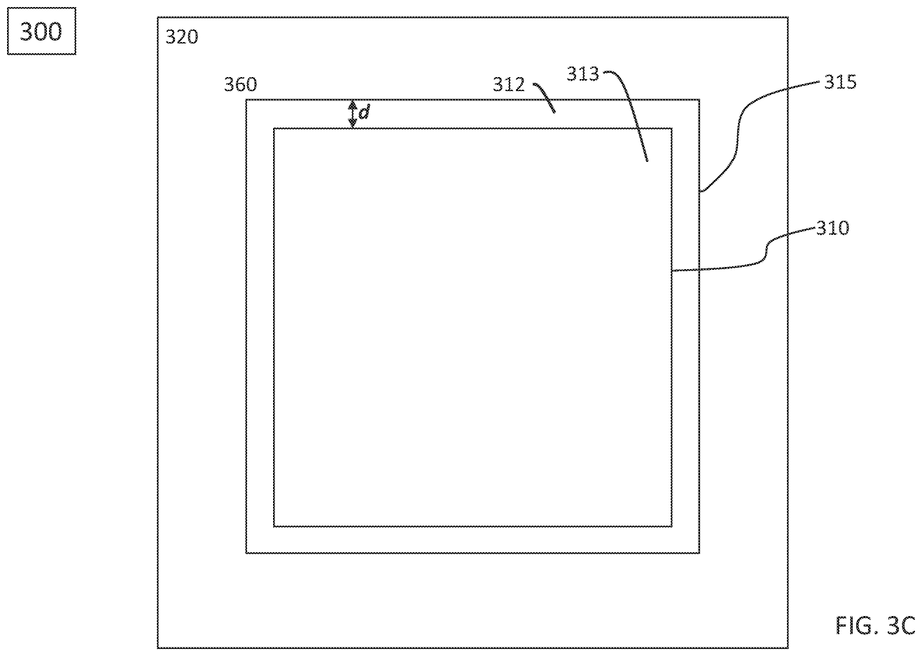

FIGS. 3A-3C show a printed circuit board 300 or section thereof according to one or more examples of the present disclosure. The PCB 300 can be implemented for reducing in unwanted radiation from a power plane. The PCB section 300 is similar to the PCB section 200 in that includes a power plane 310 and a ground plane 320. FIG. 3A shows a side view of the PCB section 300 in which the power plane 310 laterally extends parallel and above to the ground plane 320.

FIG. 3B shows a top plan view of the PCB section 300. As shown in FIG. 3B, the power plane 310 and the ground plane 320 have a rectangular shape, however, this is merely one example, and in other instances they may have any other suitable shapes including, for example, other types of closed shapes or non-polygonal shapes.

The power plane may 310 may include a first main surface 310a and a second main surface 310b, where the second main surface 310b is opposite to the first main surface 310a. As shown, the second main surface 310b can face in a direction towards the ground plane 320 while the first main surface 310a can face in a direction away from the ground plane 320. The power plane 310 may electrically couple to a power supply (not shown) and configured to distribute power.

As shown in FIGS. 3A and 3B the PCB section 300 includes a shielding structure 350. The shielding structure 350 can partially cover or mask the power plane 310. In particular, the shielding structure 350 is arranged or configured to cover a portion of the power plane 310. This covering or partial covering can reduce and remove unwanted RF radiation produced by the power plane 310 without disturbing the power plane 310 itself.

The shielding structure 350 may include a metal structure 360 and a plurality of vias 370. The plurality of vias 370 can each physically and electrically couple the metal structure 360 to the ground plane 320. The vias 370 may directly couple to the metal structure 360 or may be coupled (electrically and physically) to the metal structure 360 via an attachment structure 380. As a result of the vias 370, the shielding structure 350 and the metal structure 360 may be electrically grounded 350.

FIGS. 3A-3B show the metal structure 360 of the shielding structure 350 being in the form of a metal sheet. The metal structure 360 in FIG. 3A is shown vertically higher and above a portion of the power plane 310. FIGS. 3A and 3B show the metal structure 360 partially covering the first main surface 310a of the power plane 310.

In one or more examples, the shielding structure 350 can cover a peripheral region 312 of the power plane 310. For example, the metal structure 360 may at least cover a peripheral region 312 of the first main surface 310a of the power plane 310. Further, the shielding structure 350 while covering the peripheral region 312, may not cover a remaining inner region 313 of the first main surface 310a of the power plane 310. That the shielding structure 350 or metal structure 360 can cover the peripheral region 312 and not cover the inner region 313. In one or more instances, the shielding structure 350 or metal structure 360 is considered covering the peripheral region 312 and not covering the inner region 313 from a view facing the first main surface 310a of the power plane. Accordingly, the metal structure, from a top plan view may extend from outside the periphery 315 of the power plane to inward over the peripheral region 312.

The metal structure 360 may be in the form a ring or ring-like metal structure covers the peripheral region 312 of the power plane 310. For example, the metal structure 360 can be a ring-shaped metal sheet covering over the peripheral region 312 of the power plane 310. As shown in the example of FIG. 3B, the metal structure 360 appears as a square ring. In general, the metal structure 360 or metal sheet of the metal structure 360 can appear as a ring in shape conforming to the shape of the power plane 310. In general, for shielding structures, the shape of the metal structure 360, from a top plan view, can be correspond to the shape of the power plane.

From a top plan view, shown in FIG. 3B, the metal structure 360 covers the peripheral region 312 which includes an at the periphery 315 of the first main surface 310a. Further, in some cases, the metal structure 360 may further cover a portion of a sidewall at a periphery 315 of the power plane 310 so that the top corner 316 (encircled in FIG. 3A) at the periphery of the power plane 310 is covered. For example, the top edge may be covered at least from a top plane perspective (facing the first main surface) and a portion of the sidewall may be covered from a side view (facing the sidewall/periphery). That is, the entire edge of at the periphery 315 of the power plane 310 may be enclosed or blocked by the shielding structure 350, e.g., from a perspective facing the top edge. 316.

Accordingly, the metal structure 360 may be an L-shaped metal structure (e.g., from a side perspective) that surrounds the periphery 315 of the power plane 310. For instance, the L-shaped metal structure can be a metal sheet that is bent so as to extend in two directions, such as, for example, two perpendicular directions, e.g., a lateral direction and vertical direction.

FIG. 3C shows a top plan view of the PCB 300 without the shielding structure 350. The perspective faces the first main surface 310a of the power plane. As shown for illustration, the first main surface 310a of the power plane 310 may be considered in terms of two regions, a peripheral region 312 which is covered by the metal structure 360 and an unshielded region 313 or a region that is not covered by the shielding structure 360, e.g., from a top plan view.

In one or more examples, the peripheral region 312 may be defined a region between the periphery/edge 315 or of the power plane 310 or first main surface 310a and a certain distance d inward from the periphery/edge 315. This distance d may be a perpendicular distance from the periphery 315, and may be substantially constant around the perimeter of the first main surface. In other case, this distance d may vary around the or in different sections of the periphery 315. In short, the peripheral region 312 may a region of the power plane 310 or the first main surface 310a including and immediately adjacent to the edge 15 of the power plane 315.

As previously described, the metal structure 360 may include or be in the form of a metal sheet. This metal sheet may extend substantially parallel to the ground plane 320 and/or the power plane 310. Further, the plurality of vias or ground 370 may be arranged or located outside of the periphery 315 of the power plane 310, e.g., from a top plan view. In one or more examples, the vias 370 of the shielding structure 360 can surround the power plane 310 or surround the periphery 315 or lateral extension of power plane 310. The shielding structure 360 is electrically grounded due to the electrical coupling of the vias 370 to the ground plane 320.

Referring to FIG. 3A, the shielding structure 350 disturbs, interrupts, and/or blocks at least some of the radiation produced by the power plane 310. In particular, the fringing fields 340 are disturbed or interrupted at least by the ground vias 370. The ground vias 370 help block the fringing field leakage 340 and bypass them to PCB ground or ground plane 320.

The radiation or radiating field 330 may also be truncated or blocked at least by the metal structure 360. As shown in FIG. 3A, the radiating field 330 is shown as reduced in comparison to the corresponding radiating field 230 of FIG. 2A. The reduction in potentially interfering radiation from the power plane 310 may be achieved without the use of RF capacitors or electromagnetic interference (EMI) absorbers. That is, the PCB 300 may be implemented without RF capacitors or EMI absorbers for power plane radiation.

As a result of the presence of the shielding structure 350, there is a reduction in unwanted radiation. For example, the PCB may be part of a wireless device and the reduction in this radiation can realize a decline in RF noise for a device. The shielding structure 350 interrupts and blocks some of the near field radiation. In particular radiation produced at or near the periphery 315 of the power plane 310 is disturbed due to the grounded metal structure 360 (metal ring) arranged around and covering the edge of the power shape 310.

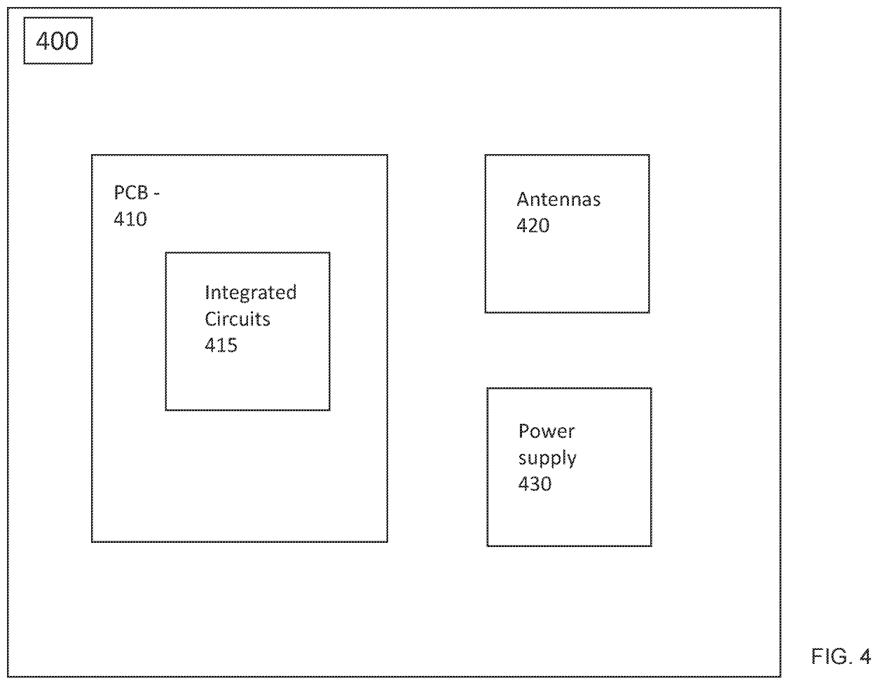

The PCB 300 may be implemented in various types of electronic devices. For example, FIG. 4 shows an exemplary electronic assembly 400. The electronic assembly may be an electronic device, such as, for example, a wireless user device, e.g., a smartphone, tablet, etc. The electronic assembly may include a PCB 410. The PCB 410 can be any of the PCBs described herein or variations thereof. For example, the PCB 410 may the same or similar to the PCB 300 of FIG. 3 and hence includes the shielding structure 350. Further, the electronic assembly 400 may additionally include integrated circuits 415 or other electronic elements that may be formed on the PCB 410. The electronic assembly may include one or more antennas 420 and at least one power supply 430. The power supply may be electrically coupled to the power plane of the PCB 410.

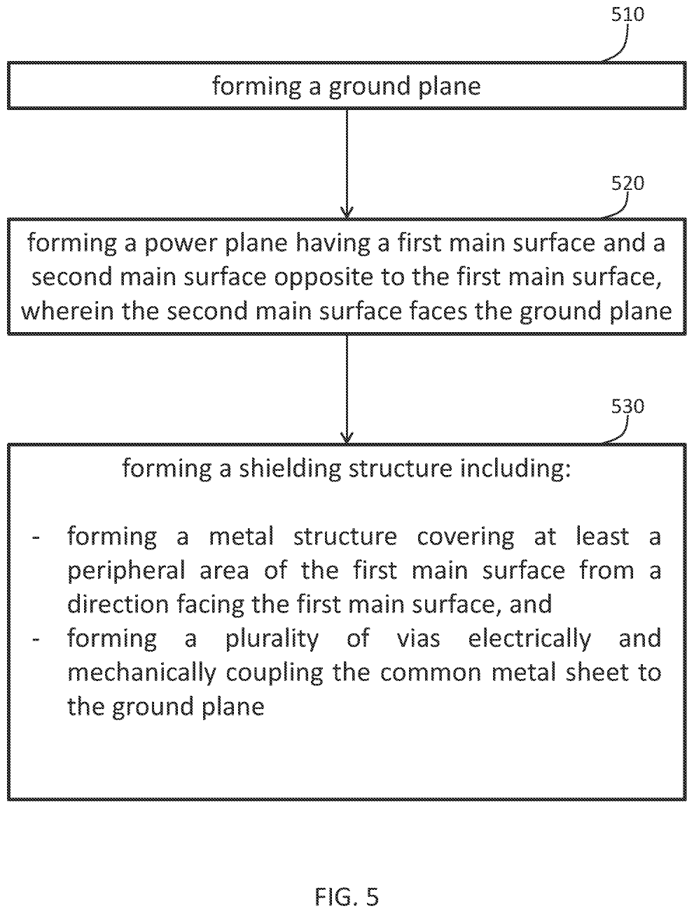

FIG. 5 is a method 500 for forming a printed circuit board according to one or more examples of the present disclosure. At 510, the method 500 includes forming a ground plane. At 520, the method 500 includes forming a power plane having a first main surface and a second main surface opposite to the first main surface, wherein the second main surface faces the ground plane. At 530 the method 500 includes forming a shielding structure including: forming a metal structure covering at least a peripheral area of the first main surface from a direction facing the first main surface, and forming a plurality of vias electrically and mechanically coupling the common metal sheet to the ground plane.

In one or more instances, the shielding structures described herein may include or made out of copper. For example, the metal structures of the shielding structures described here may include or be formed from copper metal. In the case where in the metal structure includes a metal sheet, the metal sheet may be a copper sheet or be a metal sheet including copper.

The following examples pertain to further aspects of this disclosure:

Example 1 is a printed circuit board including: a ground plane; a power plane having a first main surface and a second main surface opposite to the first main surface, wherein the second main surface faces the ground plane; and a shielding structure partially covering the power plane, the shielding structure including: a metal structure covering a peripheral area of the first main surface from a direction facing the first main surface, and a plurality of vias electrically and mechanically coupling the metal structure to the ground plane.

Example 2 is the subject matter of Example 1, wherein the plurality of vias are may be arranged around a periphery of the power plane.

Example 3 is the subject matter of Example 1 or 2, wherein the plurality of vias of the guard ring structure may extend vertically between the metal structure and the ground plane.

Example 4 is the subject matter of Example 2 or 3, wherein the plurality of vias may be evenly spaced apart.

Example 5 is the subject matter of any of Examples 1 to 4, which may further include: one or more dielectric layers, wherein at least one of the one or more dielectric layers may be arranged between the power plane and the ground plane.

Example 6 is the subject matter of any of Examples 1 to 5, wherein the power plane may extend substantially parallel to the ground plane and wherein the ground plane completely may cover the second main surface of the power plane from a vertical direction facing in a direction towards the ground plane.

Example 7 is the subject matter of any of Example 1 to 6, wherein the metal structure may include or be a metal sheet.

Example 8 is the subject matter of Example 7, wherein the metal sheet may cover the peripheral area of the first main surface from a direction facing the first main surface.

Example 9 is the subject matter of Example 7 or 8, wherein the metal sheet may extend laterally and parallel to the power plane.

Example 10 is the subject matter of any of Examples 7 to 9, wherein the metal sheet may include copper or be a copper sheet.

Example 11 is the subject matter of any of Examples 1 to 10, which may further include one or more integrated circuits disposed over the first main surface of the power plane.

Example 12 is the subject matter of Example 11, wherein the one or more integrated circuits may be electrically coupled to the power plane.

Example 13 is the subject matter of Example 12, where the one or more integrated circuits may be or include a Double data rate (DDR) integrated circuit.

Example 14 is the subject matter of any of Examples 1 to 13, wherein the shielding structure may be configured to interrupt or at least partially block fringing fields and radiating fields produced by the power plane.

Example 15 is the subject matter of any of Examples 1 to 14, wherein only a portion a portion of the first main surface of the power plane corresponding to the peripheral area may be covered and wherein a remainder of the first main surface of the power plane may be uncovered, from the direction facing the first main surface of the power plane.

Example 1A is a printed circuit board including: a ground plane; a power plane having a first main surface and a second main surface opposite to the first main surface, wherein the second main surface faces the ground plane; and a shielding structure that is electrically grounded and configured to partially cover the power plane, the shielding structure including a metal structure covering at least a top corner of the power plane located at the first main surface.

Example 2A is the subject matter of Example 1A, wherein the metal structure may completely cover the top corner along a periphery of the power plane to form a metal ring from a top view facing the first main surface.

Example 3A is the subject matter of example 2A, wherein the shape of the metal ring may conform to the periphery of the first main surface from the top view facing the first main surface.

Example 4A is the subject matter of Example 2A or 3A, wherein from a side view perpendicular to the top view, the metal structure may have an L-shape covering a portion of the first main surface a portion of a sidewall of the power plane perpendicular to the first main surface.

Example 5A is the subject matter of any of Examples 1A to 4A, wherein the shielding structure may further include a plurality of vias electrically and mechanically coupling the metal structure to the ground plane so as to electrically ground the shielding structure.

Example 1B is a method for a printed circuit board including: forming a ground plane; forming a power plane having a first main surface and a second main surface opposite to the first main surface, wherein the second main surface faces the ground plane; and forming a shield structure including
forming a common metal sheet covering at least a peripheral area of the first main surface from a direction facing the first main surface, and
forming a plurality of vias electrically and mechanically coupling the common metal sheet to the ground plane.

Example 2B is the subject matter of Example 1B, wherein the plurality of vias may be arranged around a periphery of the power plane.

Example 3B is the subject matter of Example 1B or 2B, wherein the plurality of vias of the guard ring structure may extend vertically between the common metal sheet and the ground plane.

Example 4B is the subject matter of Example 2B or 3B, wherein the plurality of vias may be evenly spaced apart.

Example 5B is the subject matter of any of Examples 1B to 4B, which may further include forming one or more dielectric layers, wherein at least one of the one or more dielectric layers is arranged between the power plane and the ground plane.

Example 6B is the subject matter of any of Examples 1B to 5B, wherein the power plane may extend substantially parallel to the ground plane and wherein the ground plane completely covers the second main surface of the power plane from a vertical direction facing in a direction towards the ground plane.

It should be noted that one or more of the features of any of the examples above may be combined with any one of the other examples.

The scope of the disclosure is thus indicated by the appended claims and all changes which come within the meaning and range of equivalency of the claims are therefore intended to be embraced.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

All acronyms defined in the above description additionally hold in all claims included herein.

What is claimed is:

1. A printed circuit board comprising:
a ground plane;
a power plane having a first main surface and a second main surface opposite to the first main surface, wherein the second main surface faces the ground plane; and
a shielding structure partially covering the power plane, the shielding structure comprising:
a metal structure covering a peripheral area of the first main surface from a direction facing the first main surface, and
a plurality of vias electrically and mechanically coupling the metal structure to the ground plane.

2. The printed circuit board of claim of 1, wherein the plurality of vias are arranged around a periphery of the power plane.

3. The printed circuit board of claim 2,
wherein the plurality of vias of the guard ring structure extend vertically between the metal structure and the ground plane.

4. The printed circuit board of claim 2,
wherein the plurality of vias are evenly spaced apart.

5. The printed circuit board of claim 1, further comprising:
one or more dielectric layers, wherein at least one of the one or more dielectric layers is arranged between the power plane and the ground plane.

6. The printed circuit board of claim 1,
wherein the power plane extends substantially parallel to the ground plane and wherein the ground plane completely covers the second main surface of the power plane from a vertical direction facing in a direction towards the ground plane.

7. The printed circuit board of claim 1,
wherein the metal structure comprises a metal sheet.

8. The printed circuit board of claim 7,
wherein the metal sheet covers the peripheral area of the first main surface from a direction facing the first main surface.

9. The printed circuit board of claim 7,
wherein the metal sheet extends laterally and parallel to the power plane.

10. The printed circuit board of claim 7,
wherein the metal sheet comprises copper.

11. The printed circuit board of claim 1, further comprising
one or more integrated circuits disposed over the first main surface of the power plane.

12. The printed circuit board of claim 11,
wherein the one or more integrated circuits are electrically coupled to the power plane.

13. The printed circuit board of claim 12,
where the one or more integrated circuits comprise a Double data rate (DDR) integrated circuit.

14. The printed circuit board of claim 1,
wherein the shielding structure is configured to interrupt or at least partially block fringing fields and radiating fields produced by the power plane.

15. The printed circuit board of claim 1,
wherein only a portion a portion of the first main surface of the power plane corresponding to the peripheral area is covered and wherein a remainder of the first main surface of the power plane is uncovered, from the direction facing the first main surface of the power plane.

16. A printed circuit board comprising:
a ground plane;
a power plane having a first main surface and a second main surface opposite to the first main surface, wherein the second main surface faces the ground plane; and
an shielding structure that is electrically grounded and configured to partially cover the power plane, the shielding structure comprising:
a metal structure covering at least a top corner of the power plane located at the first main surface.

17. The printed circuit board of claim 16,
wherein the metal structure completely covers the top corner along a periphery of the power plane to form a metal ring from a top view facing the first main surface.

18. The printed circuit board of claim 17, wherein the shape of the metal ring conforms to the periphery of the first main surface from the top view facing the first main surface.

19. The printed circuit board of claim 17,
wherein from a side view perpendicular to the top view, the metal structure has an L-shape covering a portion of the first main surface a portion of a sidewall of the power plane perpendicular to the first main surface.

20. The printed circuit board of claim 16,
wherein the shielding structure further comprises:
a plurality of vias electrically and mechanically coupling the metal structure to the ground plane so as to electrically ground the shielding structure.
